(19) United States
(12) Patent Application Publication
(10) Pub. No.: US 2026/0143595 A1
(43) Pub. Date: May 21, 2026

(54) PRINTED CIRCUIT BOARD

(71) Applicant: SAMSUNG ELECTRO-MECHANICS CO., LTD., Suwon-si (KR)

(72) Inventors: Dong Keun LEE, Suwon-si (KR); Yong Wan JI, Suwon-si (KR); Jong Eun PARK, Suwon-si (KR); Tae Hong MIN, Suwon-si (KR); Eun Heay LEE, Suwon-si (KR)

(73) Assignee: SAMSUNG ELECTRO-MECHANICS CO., LTD., Suwon-si (KR)

(21) Appl. No.: 19/187,292

(22) Filed: Apr. 23, 2025

(30) Foreign Application Priority Data
Nov. 15, 2024 (KR) 10-2024-0163323

(51) Int. Cl. H05K 1/18; H05K 1/02; H05K 1/03; H05K 1/11

(52) U.S. Cl. CPC H05K 1/183; H05K 1/0298; H05K 1/0306; H05K 1/115; H05K 2201/10015

(57) ABSTRACT

A printed circuit board includes a glass layer in which a plurality of cavity portions having different depths and/or shapes are formed. Various types of electronic components are disposed within the cavity portions based on the thickness and/or shape of the components.

### CROSS-REFERENCE TO RELATED APPLICATION(S)

This application claims benefit of priority to Korean Patent Application No. 10-2024-0163323 filed on Nov. 15, 2024 with the Korean Intellectual Property Office, the disclosure of which is incorporated herein by reference in its entirety.

### TECHNICAL FIELD

The present disclosure relates to a printed circuit board.

In order to respond to the high performance and miniaturization strategy of semiconductors, the level of miniaturization and high density required for printed circuit boards has increased. For example, in order to manufacture high-end products such as server boards, high-layer and large bodies are required. However, as the number of wiring layers increases and the body size increases, the board may become vulnerable to warpage. To solve this problem, the use of glass cores has been considered.

### SUMMARY

One aspect of the present disclosure is to form a plurality of cavities having various depths and shapes in a glass layer, and to appropriately dispose and embed various types of elements having various sizes in the plurality of cavities.

For example, a printed circuit board according to an example embodiment may include: a glass layer having first and second surfaces opposing each other; a first cavity portion penetrating between the first surface and the second surface of the glass layer; a second cavity portion penetrating through a portion of the glass layer from the first surface of the glass layer; a first electronic component disposed in the first cavity portion; and a second electronic component disposed in the second cavity portion.

For example, a printed circuit board according to an example embodiment may include: a glass layer having first and second surfaces opposing each other; a first cavity penetrating through a portion of the glass layer from the first surface of the glass layer; a second cavity penetrating through another portion of the glass layer from the first surface of the glass layer, connected to the first cavity, and having a different depth from the first cavity; a first component disposed in the first cavity; and a second component disposed in the second cavity, and having a different thickness from the first component.

As one of the various effects of the present disclosure, a printed circuit board including a glass layer may be provided, which may embed various types of devices of various sizes and may offer a high degree of design freedom.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board; and

FIG. 3 is a schematic A-A cut plan view of the printed circuit board of FIG. 2.

### DETAILED DESCRIPTION

Hereinafter, the present disclosure will be described with reference to the accompanying drawings. In the drawings, the shape and size of the elements may be exaggerated or reduced for clearer description.

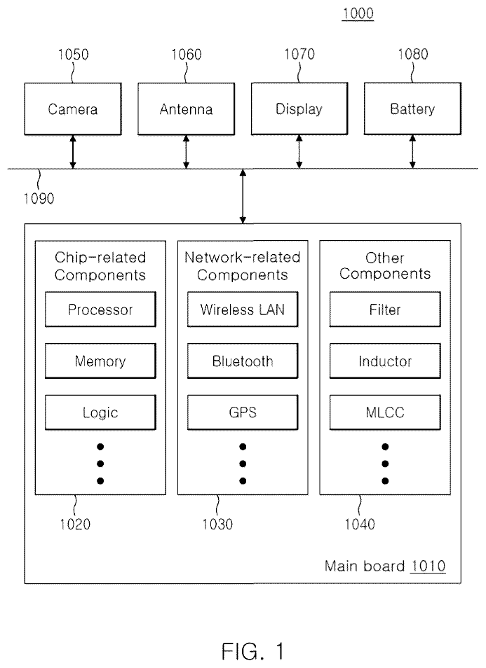

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

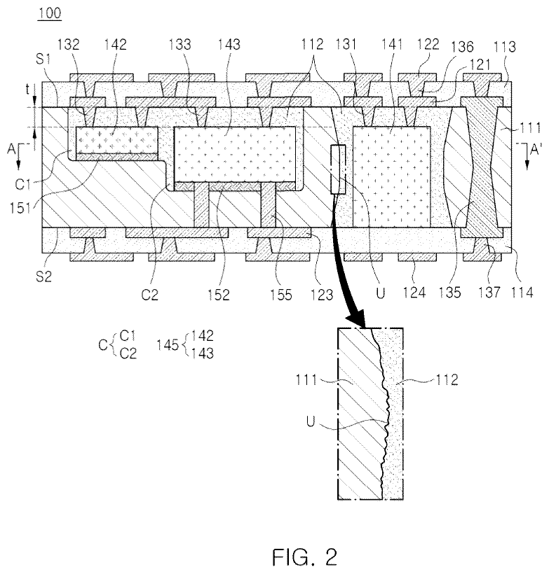

FIG. 2 is a cross-sectional view schematically illustrating an example of a printed circuit board.

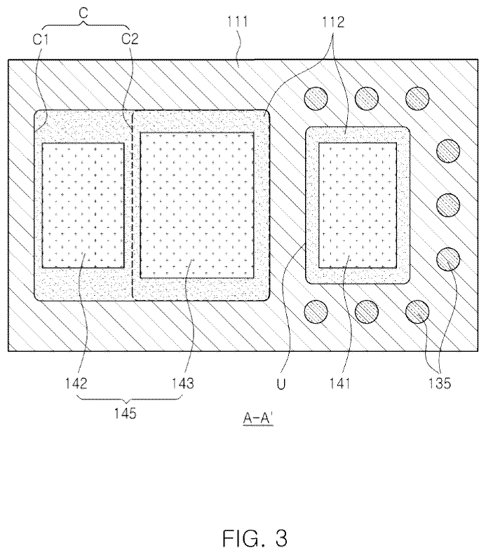

FIG. 3 is a schematic A-A cut plan view of the printed circuit board of FIG. 2.

Referring to FIGS. 2 and 3, a printed circuit board 100 according to an example embodiment may include: a glass layer 111 having a first surface S1 and a second surface S2 opposing each other, a first cavity portion H penetrating between the first surface S1 and the second surface S2 of the glass layer 111, a second cavity portion C penetrating through a portion of the glass layer 111 from the first surface S1 of the glass layer 111, a first electronic component 141 disposed in the first cavity portion H, and a second electronic component 145 disposed in the second cavity portion C. The first cavity portion H may be a through-cavity, and the second cavity portion C may be a blind cavity. The second cavity portion C may have a plurality of cavity regions. For example, the second cavity portion C may include a first cavity C1 and a second cavity C2 having different depths. The first cavity C1 and the second cavity C2 may be integrally connected to each other to form the second cavity portion C. The first electronic component 141 may be thicker than the second electronic component 145. The second electronic component 145 may include a first component 142 and a second component 143 respectively disposed in the first cavity C1 and the second cavity C2 and having different thicknesses. The first electronic component 141 and the second electronic component 145 may include different types of electronic components, and further, the first component 142 and the second component 143 may also include different types of electronic components. Here, the different types of electronic devices may include not only a case in which the functions of the devices themselves are different, such as capacitors and inductors, but also a case in which the specific performance is different even though the functions are substantially the same, such as when the capacitances are different among capacitors. Meanwhile, the electronic devices described above may be active devices and/or passive devices. For example, the electronic devices may be silicon bridges, silicon capacitors, and/or Integrated Passive Devices (IPD), but the present disclosure is not limited thereto.

Additionally, the printed circuit board 100 according to an example embodiment may further include, if necessary, an insulating material 112 filling at least portions of each of the first cavity portion H and the second cavity portion C including the first and second cavities C1 and C2, and covering at least portions of each of the first electronic component 141 and the second electronic component 145 including the first and second components 142 and 143. Additionally, if necessary, the printed circuit board 100 may further include a first connection via 131 penetrating through at least a portion of the insulating material 112 and connected to the first electronic component 141, and second and third connection vias 132 and 133 respectively penetrating through at least another portion of the insulating material 112 and respectively connected to the first and second components 142 and 143. The first electronic component 141 may be disposed in the first cavity portion H in face-up orientation, and may have an electrode connected to the first connection via 131 on a front surface thereof. The first and second components 142 and 143 may be attached to bottom surfaces of the first and second cavities C1 and C2 in face-up orientation through first and second adhesive films 151 and 152, respectively, and may have an electrode connected to the second and third connection vias 132 and 133 on the front surfaces, respectively.

In this manner, in the printed circuit board 100 according to an example embodiment, the plurality of cavity portions H and C having various depths and shapes on the glass layer 111 may be formed, and various types of electronic components 141, 142, and 143 having various sizes may be appropriately disposed in the plurality of cavity portions H and C, and may be embedded. In this case, the range of adoption of the embedded electronic components 141, 142 and 143 may be expanded and the degree of design freedom may be increased by implementing the cavity portions H and C that are not restricted by size. Additionally, upper insulation distances of different embedded electronic components 141, 142 and 143 may be designed to be substantially the same, in which case the sizes of connection vias 131, 132 and 133 formed in the insulating material 112 may be made substantially the same, and the signal transmission path may be substantially unified. Additionally, a design in which an interconnection between electronic components 141, 142 and 143 is shortened may also be possible, in which case high reliability against signal noise or the like, may be expected. Additionally, a signal path between the electronic components 141, 142 and 143 embedded in the substrate 100 and the semiconductor chip mounted on the substrate 100 may be reduced, and power loss may be reduced, which may be advantageous for high-speed signal transmission. In this case, the printed circuit board 100 may be easily applied to a server CPU or AI accelerator. Meanwhile, the first and second cavity portions H and C, and the first and second cavities C1 and C2 of the second cavity portion C, may be easily implemented in the glass layer 111 by adjusting the conditions of laser processing and fixing conditions such as etching concentration and time.

In this respect, as a non-limiting example, the second cavity C2 may be deeper than the first cavity C1, and the second component 143 disposed in the second cavity C2 may be thicker than the first component 142 disposed in the first cavity C1. Accordingly, the second and third connection vias 132 and 133 may have substantially the same thickness t as each other. If necessary, the first connection via 131 may also have substantially the same thickness t as each of the second and third connection vias 132 and 133. Meanwhile, in the size and arrangement relationship, the first electronic component 141 may include an Integrated Passive Device (IPD), the first component 142 may include a silicon bridge, and the second component 143 may include a silicon capacitor, but the present disclosure is not limited thereto.

Meanwhile, in the first cavity portion H, at least a portion of the wall surface may have an uneven portion U. Accordingly, adhesion with the insulating material 112 may be secured. The roughness of the uneven portion U may be, for example, greater than the roughness of the first surface S1 and/or the second surface S2 of the glass layer 111. Additionally, the second cavity portion C, more specifically, each of the first and second cavities C1 and C2, may have a rounded shape at a corner of a bottom surface thereof, and may have a structure in which a slope is formed in a length or a width of, for example, 50 μm or less from each wall surface. Accordingly, the insulating material 112 may be filled almost without voids within the second cavity portion C, more specifically, the first and second cavities C1 and C2. Additionally, bottom surface of each of the second cavity portions C, more specifically, the first and second cavities C1 and C2, may have a uniform average roughness Ra of approximately 1 μm to 2 μm. Accordingly, the adhesion with the first and second adhesive films 151 and 152 may be strengthened, and the first and second components 142 and 143 may be fixed by minimizing tilt. As a result, the performance of each of the first electronic component 141 and the second electronic component 145, including the first and second components 142 and 143, may be maintained, and the reliability of the printed circuit board 100 may thereby be increased.

The printed circuit board 100 according to an example embodiment may, if necessary, further include a metal member 155 penetrating through the glass layer 111 and the second adhesive film 152 together from the second surface S2 of the glass layer 111, and connected to a back surface of the second component 143, in a region overlapping the second cavity C2 of the glass layer 111 on a plane. For example, when heat dissipation of the second component 143 is required, the metal member 155 having such a form may be formed to increase the heat dissipation effect. However, the present disclosure is not limited thereto, and, if necessary, in a similar form to the metal member 155, an additional metal member may be further included, which penetrates through the glass layer 111 and the first adhesive film 151 together from the second surface S2 of the glass layer 111 and is connected to a back surface of the first component 142, in a region overlapping the first cavity C1 of the glass layer 111 on a plane. Meanwhile, the metal member 155 or the additional metal member may also be used for electrical connection purposes, or the like, if necessary, in addition to the heat dissipation purpose described above.

The printed circuit board 100 according to an example embodiment may, if necessary, further include a first wiring layer 121 which is disposed at the first surface S1 of the glass layer 111, in which at least a portion thereof is disposed on the insulating material 112 and which is connected to the first to third connection vias 131, 132 and 133, respectively, a first insulating layer 113 disposed at the first side S1 of the glass layer 111 and covering at least portions of each of the glass layer 111 and the insulating material 112 and at least a portion of the first wiring layer 121, a second wiring layer 122 disposed on the first insulating layer 113, and/or a first via layer 136 disposed within the first insulating layer 113 and connecting at least portions of each of the first and second wiring layers 121 and 122 to each other. For example, a build-up layer may be formed at the first surface S1 of the glass layer 111. In this case, one or more semiconductor chips may be mounted on the build-up layer and electrically connected to the first and second electronic components 141 and 145, respectively. For example, the printed circuit board 100 may include the glass layer 111 as a core layer and may be used as a package substrate or interposer substrate built up on at least one side.

Additionally, the printed circuit board 100 according to an example embodiment may, if necessary, further include a third wiring layer 123 disposed at the second surface S2 of the glass layer 111, a second insulating layer 114 disposed at the second surface S2 of the glass layer 111 and covering at least portions of each of the glass layer 111 and the insulating material 112 and at least a portion of the third wiring layer 123, a fourth wiring layer 124 disposed on the second insulating layer 114, a second via layer 137 disposed within the second insulating layer 114 and connecting at least portions of each of the third and fourth wiring layers 123 and 124 to each other, and/or a through-via 135 penetrating between the first surface S1 and the second surface S2 of the glass layer 111 and connecting at least portions of each of the first and third wiring layers 121 and 123 to each other. The metal member 155 may be connected to at least a portion of the third wiring layer 123. For example, a build-up layer may also be formed at the second surface S2 of the glass layer 111. For example, the printed circuit board 100 may include the glass layer 111 as a core layer and may be a package substrate or an interposer substrate built up on both sides.

The printed circuit board 100 according to an example embodiment may further include a frame having a through-portion as needed, and in this case, the glass layer 111 may be disposed within the through-portion of the frame. Additionally, a space between the frame and the glass layer 111 may be filled with one or more of the first and second insulating layers 113 and 114, or may be filled with a separate filler. The frame may include a material having excellent rigidity, and may include, for example, Copper Clad Laminate (CCL) or Unclad CCL, but the present disclosure is not limited thereto. For example, the frame may include other organic materials having excellent rigidity, may include other types of inorganic materials having excellent rigidity. The frame may be used as a jig during the process, and thus the process may be performed on the panel level through the frame. Additionally, the frame may remain in a final unit after singulation, which may be advantageous for warpage control.

Hereinafter, components of a printed circuit board 100 according to an example embodiment will be described in more detail with reference to the drawings.

The glass layer 111 may include glass, which is an amorphous solid. The glass may include, for example, pure silicon dioxide (about 100% SiO₂), soda lime glass, borosilicate glass, alumino-silicate glass, etc. However, the present disclosure is not limited thereto, and alternative glass materials, such as fluorine glass, phosphate glass, chalcogen glass, and the like, may also be used. Additionally, other additives may be further included to form a glass having specific physical properties. These additives may include not only calcium carbonate (e.g., lime) and sodium carbonate (e.g., soda), but also magnesium, calcium, manganese, aluminum, lead, boron, iron, chromium, potassium, sulfur, and antimony, and carbonates and/or oxides of these elements and other elements. Meanwhile, the glass layer 111 may be distinguished from an organic insulating material including glass fiber (Glass Fiber, Glass Cloth or Glass Fabric), such as Copper Clad Laminate (CCL), Prepreg (PPG). The glass layer 111 may be in the form of, for example, a glass plate.

The insulating material 112 may include an organic insulating material. The organic insulating material may include a thermosetting resin such as an epoxy resin, a thermoplastic resin such as a polyimide, or an inorganic filler and/or an organic filler together with the resin. For example, the organic insulating material may include an Ajinomoto Build-up Film (ABF) and Photo imageable Dielectric (PID), but the present disclosure is not limited thereto. One surface and the other surface of the insulating material 112 may be substantially coplanar with the first surface S1 and the second surface S2 of the glass layer 111, but the present disclosure is not limited thereto. If necessary, the insulating material 112 may be filled with the first insulating layer 113. In this case, the insulating material 112 may be integrated with the first insulating layer 113 without a boundary.

Each of the first and second insulating layers 113 and 114 may include an organic insulating material. The organic insulating material may include a thermosetting resin such as an epoxy resin, a thermoplastic resin such as a polyimide, or an inorganic filler, an organic filler, and/or glass fiber (glass cloth, glass fabric) along with the resin. For example, the organic insulating material may include Prepreg (PPG), an Ajinomoto Build-up Film (ABF), and Photo imageable Dielectric (PID), but the present disclosure is not limited thereto. Each of the first and second insulating layers 113 and 114 may be formed of a plurality of layers. In this case, each of the plurality of layers may be integrated without a boundary, or the boundary between the layers may be identified. Additionally, each of the multiple layers may include substantially the same insulating material, but may also include different insulating materials.

Each of the first to fourth wiring layers 121, 122, 123 and 124 may include a metal. The metal may include copper (Cu), aluminum (Al), silver (Ag), tin (Sn), gold (Au), nickel (Ni), lead (Pb), titanium (Ti), and/or alloys thereof. For example, each of the first to fourth wiring layers 121, 122, 123, and 124 may include chemical copper formed by electroless plating as a seed layer, and may include electrolytic copper formed by electrolytic plating as a pattern plating layer based thereon. However, if necessary, titanium layers and copper layers formed by sputtering may be included as seed layers. The first to fourth wiring layers 121, 122, 123, and 124 may each perform various functions according to the design. For example, the first to fourth wiring layers 121, 122, 123, and 124 may include a signal pattern, a power pattern, and a ground pattern. Each of the patterns may have various shapes such as a line, a trace, a plane, and a pad. The pad may be a concept that includes a land. Each of the second and fourth wiring layers 122 and 124 may be formed of a plurality of layers. The second and fourth wiring layers 122 and 124 may have the same number of layers, but the present disclosure is not limited thereto, and may have different numbers of layers. For example, the second wiring layer 122 may have more layers than the fourth wiring layer 124.

Each of the first to third connection vias 131, 132 and 133 may include a metal. The metal may include copper (Cu), aluminum (Al), silver (Ag), tin (Sn), gold (Au), nickel (Ni), lead (Pb), titanium (Ti), and/or alloys thereof. For example, each of the first to third connection vias 131, 132 and 133 may include chemical copper formed by electroless plating as a seed layer, and may include electrolytic copper formed by electrolytic plating as a pattern plating layer based thereon. However, if necessary, a titanium layer and a copper layer formed by sputtering may be included as seed layers. The first to third connection vias 131, 132 and 133 may perform various functions depending on the design. For example, the first to third connection vias 131, 132 and 133 may include a connection via for signal transmission, a connection via for power transmission, and a connection via for ground transmission. Each of the first to third connection vias 131, 132 and 133 may include a filled via in which a via hole is filled with a metal, but may also include a conformal via in which the metal is disposed along a wall surface of the via hole. Each of the first to third connection vias 131, 132 and 133 may have a shape tapered in the same direction. Each of the first to third connection vias 131, 132 and 133 may be provide in plural.

The through-via 135 may include a metal. The metal may include copper (Cu), aluminum (Al), silver (Ag), tin (Sn), gold (Au), nickel (Ni), lead (Pb), titanium (Ti), and/or alloys thereof. For example, the through-via 135 may include a titanium layer and a copper layer formed by sputtering as seed layers, and may include electrolytic copper formed by electrolytic plating as a pattern plating layer based on the titanium and copper layers. However, if necessary, the through-via 135 may include chemical copper formed by electroless plating as a seed layer. The through-via 135 may perform various functions depending on the design. For example, the through-via 135 may include a through-via for signal transmission, a through-via for power transmission, and a through-via for ground transmission. The through-via 135 may include a filled via in which a through-hole is filled with a metal, but may also include a conformal via in which the metal is disposed along a wall surface of the through-hole and an interior thereof is filled with a filler. The through-via 135 may have an hourglass shape, but may also have a cylindrical shape. The through-via 135 may be provided in plural. The through-via 135 may have a landless or pad less structure as needed, and in this case, the through-via 135 may be directly connected to the connection vias of each of the first and second via layers 136 and 137 without a pad or land.

Each of the first and second via layers 136 and 137 may include a metal. The metal may include copper (Cu), aluminum (Al), silver (Ag), tin (Sn), gold (Au), nickel (Ni), lead (Pb), titanium (Ti), and/or alloys thereof. For example, each of the first and second via layers 136 and 137 may include chemical copper formed by electroless plating as a seed layer, and may include electrolytic copper formed by electrolytic plating as a pattern plating layer based on the chemical copper. However, if necessary, the first and second via layers 136 and 137 may include a titanium layer and a copper layer formed by sputtering as seed layers. Each of the first and second via layers 136 and 137 may perform various functions depending on the design. For example, the first and second via layers 136 and 137 may include a connection via for signal transmission, a connection via for power transmission, and a connection via for ground transmission. Each of the first and second via layers 136 and 137 may include a filled via in which a via hole is filled with a metal, but may also include a conformal via in which the metal is disposed along a wall surface of the via hole. The connection vias included in each of the first and second via layers 136 and 137 may have shapes that are tapered in opposite directions. Each of the first and second via layers 136 and 137 may include a plurality of connection vias. Each of the first and second via layers 136 and 137 may be formed of a plurality of layers. The first and second via layers 136 and 137 may have the same number of layers, but the present disclosure is not limited thereto, and may have different numbers of layers. For example, the number of layers of the first via layer 136 may be greater than the number of layers of the second via layer 137.

Each of the first and second electronic components 141 and 145 may include at least one of an active component and a passive component. Each of the active component and the passive component may be in the form of an integrated circuit die or a chip type component type, but the present disclosure is not limited thereto. Each of the active component and the passive component may be a silicon bridge, a silicon capacitor, and/or an Integrated Passive Device (IPD), but the present disclosure is not limited thereto. The number of active components and/or passive components included in the first and second electronic components 141 and 145 may not be particularly limited. The active and/or passive components of the first and second components 142 and 143 included in the second electronic component 145 may be attached to bottom surfaces of the first and/or second cavities C1 and C2 respectively through the first and/or second adhesive films 151 and 152. Each of the first and second adhesive films 151 and 152 may include a Die Attach Film (DAF). The DAF (Die Attach Film) may be, for example, an epoxy-based film, a silicon-based film, an acrylic-based film, or the like, but the present disclosure is not limited thereto.

The metal member 155 may include a metal. The metal may include copper (Cu), aluminum (Al), silver (Ag), tin (Sn), gold (Au), nickel (Ni), lead (Pb), titanium (Ti), and/or alloys thereof. For example, the metal member 155 may include chemical copper formed by electroless plating as a seed layer, and may include electrolytic copper formed by electrolytic plating as a pattern plating layer based on this. However, if necessary, the metal member 155 may include a titanium layer and a copper layer formed by sputtering as seed layers. The metal member 155 may be a dummy member formed for heat dissipation purposes, but is not limited thereto, and may be used as a member for signal, power, and/or ground transmission, if necessary. The metal member 155 may be in the form in which a through-hole penetrating the glass layer 111 and the second adhesive film 152 at once is filled with metal, but the present disclosure is not limited thereto. The metal member 155 may have a cylindrical shape, but is not limited thereto. The metal member 155 may be provided in plural.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component.

In the present disclosure, being disposing in a cavity portion, a cavity, a through-portion or a through-hole may include not only a case in which an object is disposed completely in the cavity portion, the cavity, the through-portion or the through-hole, but also a case in which the object protrudes upwardly or downwardly in a cross-section. For example, when the object may be disposed within the cavity portion, the cavity, the through-portion or the through-hole on a plane, the object may be determined to be disposed within the cavity portion, the cavity, the through-portion or the through-Hole hole in a broader sense.

In the present disclosure, determination may be performed by including process errors, positional deviations, errors at the time of measurement, which may occur in a manufacturing process. For example, substantially the same direction may include not only the completely same direction but also the approximately the same direction. Furthermore, substantially coplanar may include not only the case of being completely coplanar but also the case of being approximately coplanar. Furthermore, substantially having a specific shape may include not only the case of having such a shape completely but also the case of having such a shape approximately. Furthermore, substantially the same insulating material may mean not only the case of being the completely same insulating material but also the case of including the same type of insulating material. Accordingly, the composition of the insulating material may be substantially the same, although the specific composition ratios may vary slightly.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure serve solely to describe an example embodiment and are not intended to limit the present disclosure. In this context, singular terms include their plural forms unless the context clearly indicates otherwise.

What is claimed is:

1. A printed circuit board, comprising:
a glass layer having first and second surfaces opposing each other;
a first cavity portion penetrating between the first surface and the second surface of the glass layer;
a second cavity portion penetrating through a portion of the glass layer from the first surface of the glass layer;
a first electronic component disposed in the first cavity portion; and
a second electronic component disposed in the second cavity portion.

2. The printed circuit board according to claim 1,
wherein each of the first and second electronic components includes at least one of an active component and a passive component.

3. The printed circuit board according to claim 1,
wherein at least a portion of a wall surface of the first cavity portion has an uneven portion, and
the second cavity portion has a rounded shape at a corner of a bottom surface.

4. The printed circuit board according to claim 1,
wherein the second cavity portion includes a first cavity, and a second cavity having a deeper depth than the first cavity, and
the second electronic component includes a first component disposed in the first cavity, and a second component disposed in the second cavity and having a thickness greater than a thickness of the first component.

5. The printed circuit board according to claim 4,
wherein the first and second cavities are integrally connected to each other.

6. The printed circuit board according to claim 4,
wherein the first electronic component has a thickness greater than a thickness of each of the first and second components.

7. The printed circuit board according to claim 4,
wherein the first electronic component includes an Integrated Passive Device (IPD),
the first component includes a silicon bridge, and
the second component includes a silicon capacitor.

8. The printed circuit board according to claim 4,
wherein the first component is attached to a bottom surface of the first cavity through a first adhesive film, and the second component is attached to a bottom surface of the second cavity through a second adhesive film.

9. The printed circuit board according to claim 8, further comprising:
a metal member penetrating through the glass layer and the second adhesive film together from the second surface of the glass layer and connected to a back surface of the second component, in a region that overlaps the second cavity of the glass layer in a planar view.

10. The printed circuit board according to claim 8, further comprising:
an insulating material filling at least portions of each of the first cavity portion and the second cavity portion including the first and second cavities, and covering at least portions of each of the first electronic component and the second electronic component including the first and second components;
a first connection via penetrating through at least a portion of the insulating material and connected to the first electronic component; and
second and third connection vias penetrating through at least another portion of the insulating material and connected to the first and second components respectively,
wherein the second and third connection vias have substantially the same thickness.

11. The printed circuit board according to claim 10, further comprising:
a first wiring layer which is disposed on a first surface of the glass layer, in which at least a portion thereof is disposed on the insulating material, and connected to each of the first to third connection vias, respectively;
a first insulating layer disposed on the first surface of the glass layer, and covering at least portions of each of the glass layer and the insulating material and at least a portion of the first wiring layer;
a second wiring layer disposed on the first insulating layer; and
a first via layer disposed within the first insulating layer, and configured to connect at least portions of each of the first and second wiring layers to each other.

12. The printed circuit board according to claim 11, further comprising:
a third wiring layer disposed on a second surface of the glass layer;
a second insulating layer disposed on the second surface of the glass layer, and covering at least portions of each of the glass layer and the insulating material and at least a portion of the third wiring layer;
a fourth wiring layer disposed on the second insulating layer;
a second via layer disposed within the second insulating layer, and configured to connect at least portions of each of the third and fourth wiring layers to each other; and
a through-via penetrating between the first surface and the second surface of the glass layer, and configured to connect at least portions of each of the first and third wiring layers to each other.

13. A printed circuit board, comprising:
a glass layer having first and second surfaces opposing each other;
a first cavity penetrating through a portion of the glass layer from the first surface of the glass layer;
a second cavity penetrating through another portion of the glass layer from the first surface of the glass layer, connected to the first cavity, and having a different depth from the first cavity;
a first component disposed in the first cavity; and
a second component disposed in the second cavity, and having a different thickness from the first component.

14. The printed circuit board according to claim 13,
wherein each of the first and second cavities has a bottom surface, and
each of the first and second components is attached to the bottom surfaces of the first and second cavities, respectively, through first and second adhesive films.

15. The printed circuit board according to claim 14,
wherein each of the first and second components is a silicon bridge, a silicon capacitor, or an Integrated Passive Device (IPD).

16. The printed circuit board according to claim 15, further comprising:
an insulating material filling at least portions of each of the first and second cavities and covering at least portions of each of the first and second components;
a wiring layer disposed on the first surface of the glass layer with at least a portion thereof is disposed on the insulating material; and
first and second connection vias penetrating through at least portions of the insulating material and connecting the wiring layer to the first and second components respectively,
wherein the first and second connection vias have substantially the same thickness.

17. A printed circuit board, comprising:
a glass layer having first and second surfaces opposing each other and disposed within a through-portion of a frame;
a first cavity portion penetrating the glass layer;
an electronic component disposed in the first cavity portion; and
a first insulating layer filling at least a portion of the first cavity portion and covering at least a portion of the electronic component,
wherein a space between the frame and the glass layer is filled with the first insulating layer or a separate filler.

18. The printed circuit board according to claim 17,
wherein the frame includes a copper clad laminate (CCL) or an unclad copper clad laminate (unclad CCL).
